(19) United States
(12) Patent Application Publication
(10) Pub. No.: US 2024/0213743 A1
(43) Pub. Date: Jun. 27, 2024

(54) RIDGE-TYPE SEMICONDUCTOR OPTICAL DEVICE

(71) Applicant: Lumentum Operations, LLC, San Jose, CA (US)

(72) Inventors: Kouji NAKAHARA, Tokyo (JP); Kazuki SUGA, Kanagawa (JP)

(21) Appl. No.: 18/301,098

(22) Filed: Apr. 14, 2023

(30) Foreign Application Priority Data
Dec. 21, 2022 (JP) 2022-204353
Feb. 13, 2023 (JP) 2023-020180

(51) Int. Cl. H01S 5/227; H01S 5/028; H01S 5/042

(52) U.S. Cl. CPC H01S 5/227; H01S 5/0282; H01S 5/04256

(57) ABSTRACT

A ridge-type semiconductor optical device includes: a substrate; a mesa stripe structure on the substrate, the mesa stripe structure extending in a first direction, the mesa stripe structure comprising a brittle material; an electrode pattern including a ridge electrode on the mesa stripe structure; a pair of projection structures on the substrate and on both sides of the mesa stripe structure in a second direction perpendicular to the first direction; and a protection film on each projection structure, the protection film being separated from the electrode pattern, the protection film comprising a ductile material, the protection film and a corresponding one of the pair of projection structures being aligned at edges toward at least one orientation along the first direction, the protection film having a top higher from the substrate than a top of the ridge electrode.

### CROSS-REFERENCE TO RELATED APPLICATIONS

The present application claims priority to Japanese patent application number 2022-204353 filed on Dec. 21, 2022 and to Japanese patent application number 2023-020180 filed on Feb. 13, 2023, the contents of which are hereby incorporated by reference into this application.

### TECHNICAL FIELD

The present disclosure relates generally to a ridge-type semiconductor optical device.

### BACKGROUND

A ridge-type semiconductor optical device equipped with a mesa stripe structure can serve as a light source for optical communications. The mesa stripe structure can be formed by carving a semiconductor multilayer, laminated on a substrate, at a pair of spaced regions, making it likely to leave projection structures outside the carved pair of regions.

The projection structures could prevent damage to the mesa stripe structure, but they are the same height as and made of the same material as the mesa stripe structure, and are therefore insufficient as protective portions.

### SUMMARY

Some implementations disclosed herein prevent damage to a mesa stripe structure.

In some implementations, a ridge-type semiconductor optical device includes: a substrate; a mesa stripe structure on the substrate, the mesa stripe structure extending in a first direction, the mesa stripe structure being made of a brittle material; an electrode pattern including a ridge electrode on the mesa stripe structure; a pair of projection structures on the substrate and on both sides of the mesa stripe structure in a second direction perpendicular to the first direction; and a protection film on each of the pair of projection structures, the protection film being separated from the electrode pattern, the protection film being made of a ductile material, the protection film and a corresponding one of the pair of projection structures being aligned at edges toward at least one orientation along the first direction, the protection film having a top higher from the substrate than a top of the ridge electrode.

### BRIEF DESCRIPTION OF THE DRAWINGS

FIG. 1 is a plan view of a ridge-type semiconductor optical device in a first example implementation.

FIG. 2 is a II-II cross-sectional view of the ridge-type semiconductor optical device in FIG. 1.

FIG. 3 is a III-III cross-sectional view of the ridge-type semiconductor optical device in FIG. 1.

FIG. 4 is a plan view of a ridge-type semiconductor optical device in a second example implementation.

FIG. 5 is a V-V cross-sectional view of the ridge-type semiconductor optical device in FIG. 4.

FIG. 6 is a plan view of a ridge-type semiconductor optical device in a third example implementation.

FIG. 7 is a VII-VII cross-sectional view of the ridge-type semiconductor optical device in FIG. 6.

FIG. 8 is a plan view of the ridge-type semiconductor optical device in a fourth example implementation.

FIG. 9 is a IX-IX cross-sectional view of the ridge-type semiconductor optical device in FIG. 8.

FIG. 10 is a X-X cross-sectional view of the ridge-type semiconductor optical device in FIG. 8.

FIG. 11 is a plan view of a ridge-type semiconductor optical device in a fifth example implementation.

FIG. 12 is a XII-XII cross-sectional view of the ridge-type semiconductor optical device in FIG. 11.

FIG. 13 is a plan view of a ridge-type semiconductor optical device in a sixth example implementation.

FIG. 14 is a XIV-XIV cross-sectional view of the ridge-type semiconductor optical device in FIG. 13.

FIG. 15 is a XV-XV cross-sectional view of the ridge-type semiconductor optical device in FIG. 13.

FIG. 16 is a cross-sectional view of a ridge-type semiconductor optical device in a modification of the sixth example implementation.

FIG. 17 is a plan view of a ridge-type semiconductor optical device in a seventh embodiment.

FIG. 18 is an XVIII-XVIII cross-sectional view of the ridge-type semiconductor optical device in FIG. 17.

FIG. 19 is a XIX-XIX cross-sectional view of the ridge-type semiconductor optical device in FIG. 17.

FIG. 20 is a plan view of a ridge-type semiconductor optical device in an eighth example implementation.

FIG. 21 is a XXI-XXI cross-sectional view of the ridge-type semiconductor optical device in FIG. 20.

### DETAILED DESCRIPTION

Some implementations are specifically described in detail in the following with reference to drawings. In the drawings, the same members are denoted by the same reference numerals and have the same or equivalent functions, and a repetitive description thereof may be omitted for the sake of simplicity. Note that, the drawings referred to in the following are only for illustrating the example implementations, and are not necessarily drawn to scale.

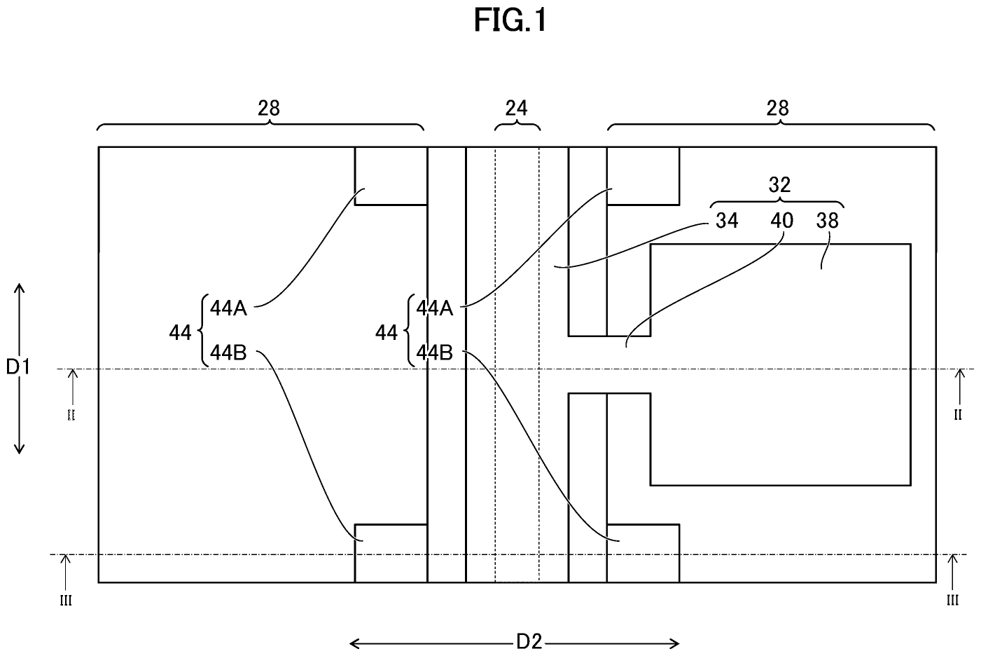

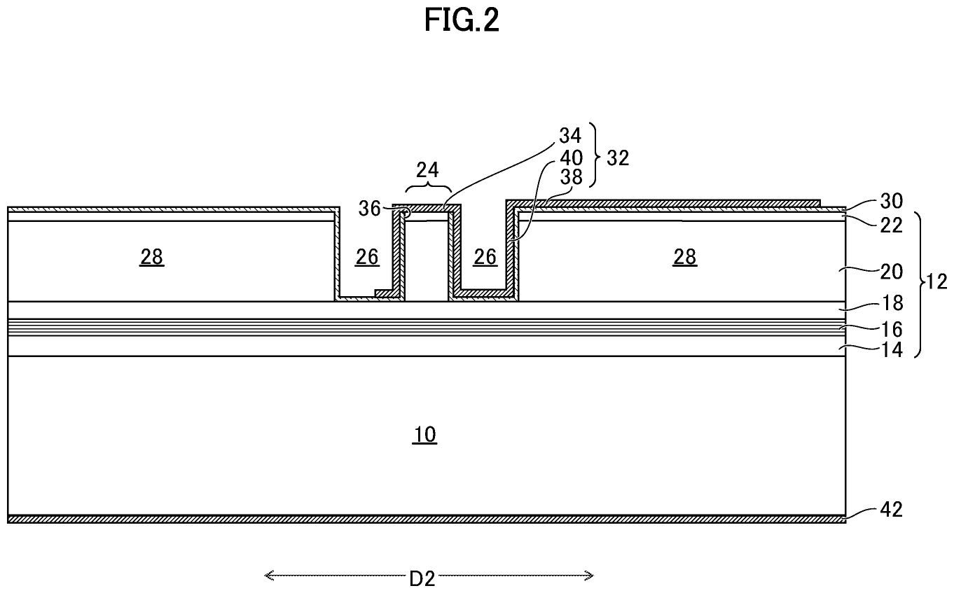

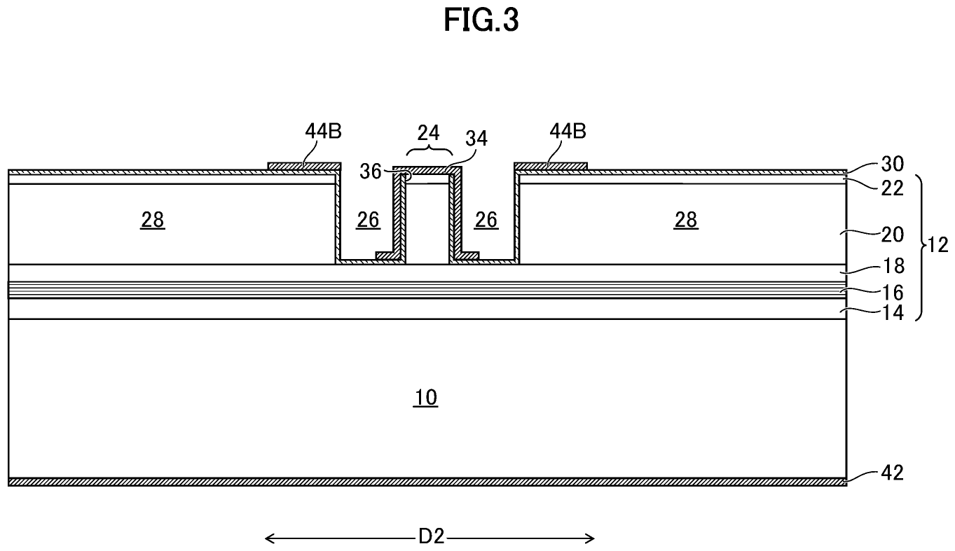

FIG. 1 is a plan view of a ridge-type semiconductor optical device in a first example implementation. FIG. 2 is a II-II cross-sectional view of the ridge-type semiconductor optical device in FIG. 1. FIG. 3 is a III-III cross-sectional view of the ridge-type semiconductor optical device in FIG. 1.

The ridge-type semiconductor optical device may be a 1.3-μm-band direct modulation semiconductor laser for 56 Gbps-operation, may support other operating speeds and wavelength bands, and may be not only a direct modulation laser but also an optical device with other optical functions, such as a continuous wave (CW) laser, an electro-absorption modulator, or a photodetector.

The ridge-type semiconductor optical device may have a substrate 10. The substrate 10 may comprise a semiconductor of a first conductivity type. There may be a laminate 12 on the substrate 10. The laminate 12 may comprise a semiconductor and may include a lower SCH (Separate Confinement Heterostructure) layer 14 of a first conductivity, an active layer 16, an upper SCH layer 18 of a second conductivity, a clad layer 20 of the second conductivity, and a contact layer 22 of the second conductivity. Herein, the first conductivity type may be an n-type and the second conductivity type may be a p-type, or vice versa. The active layer 16 may be a multi-quantum well (MQW), where well layers and barrier layers may be laminated. One end facet of the laminate 12 may be an input or output surface of light.

The ridge-type semiconductor optical device may have a mesa stripe structure 24. The mesa stripe structure 24 may be on the substrate 10 and may extend in a first direction D1. The mesa stripe structure 24 may comprise a brittle material (e.g., a semiconductor).

The mesa stripe structure 24 may be part of the laminate 12. The laminate 12 may have grooves 26 on both sides of the mesa stripe structure 24. Each groove 26 may separate the clad layer 20, separates the contact layer 22, and extends in the first direction D1. The mesa stripe structure 24 may include the clad layer 20 and the contact layer 22. An unillustrated diffraction grating layer may be included between the upper SCH layer 18 and the clad layer 20.

The ridge-type semiconductor optical device may have a pair of projection structures 28. Each projection structure 28 may extend in the first direction D1. The pair of projection structures 28 may be on both sides of the mesa stripe structure 24 in a second direction D2 perpendicular to the first direction D1, on the substrate 10. Each projection structure 28 and the mesa stripe structure 24 may be separated by a groove 26. The substrate 10 and each projection structure 28 may be aligned at edges in a direction away from the mesa stripe structure 24.

The projection structure 28, which may be another part of the laminate 12, may have a clad layer 20 and a contact layer 22. The mesa stripe structure 24, the groove 26, and the projection structure 28 may be formed in the first direction D1 from one end to another of the substrate 10. The projection structure 28 may have a side opposite to the mesa stripe structure 24, the side constituting part of a side of the ridge-type semiconductor optical device.

The ridge-type semiconductor optical device on a surface may have a passivation film 30, an insulating film, to protect semiconductor layers from the external environment. The passivation film 30 may be on a top of the projection structure 28, an inner surface of the groove 26, and a side of the mesa stripe structure 24.

The ridge-type semiconductor optical device may have an electrode pattern 32. The electrode pattern 32 may have a multi-layered structure where Ti/Pt/Au layers may be laminated in this order from the laminate 12. A passivation film 30 may be interposed between the laminate 12 and the electrode pattern 32, except on at least part of the top of the mesa stripe structure 24.

The electrode pattern 32 may include a ridge electrode 34 on the mesa stripe structure 24. The ridge electrode 34 may have both edges, in the first direction D1, aligned with respective both edges of the mesa stripe structure 24. The passivation film 30 may avoid being under the ridge electrode 34. The passivation film 30 may have a through-hole 36 for connecting the ridge electrode 34 and the contact layer 22. The ridge electrode 34 may extend in the second direction D2 and to the side of the mesa stripe structure 24. The ridge electrode 34 may have a side edge in the groove 26, but may not extend to the projection structure 28.

The electrode pattern 32 may include a pad electrode 38. The pad electrode 38 may be on one of the pair of projection structures 28. The pad electrode 38 may have a planar shape that may be smaller than the top of the projection structure 28. The pad electrode 38 may be used for external electrical connection, such as for an unillustrated wire to be bonded to it, or to be bonded with solder.

When the electrode pattern 32 is uniform in width in the first direction D1 from the top of the mesa stripe structure 24 to the top of the pair of projection structures 28, it may serve as a wide protective layer, but this may increase parasitic capacitance and hinder high-speed operation. For high-speed operation at 56 Gbps or higher (e.g., greater than or equal to 56 Gbps), the parasitic capacitance may need to be sufficiently small. In addition, an increase in size of the electrode pattern 32 may results in a greater stress generated in a layer under it, which may make it likely to degrade characteristics.

In this example implementation, the side edge of the ridge electrode 34 does not reach the top of the projection structure 28, thereby preventing an increase in size. This enables high-speed operation because the parasitic capacitance is not larger, which therefore enables suppression of characteristic degradation because the stress is smaller.

The electrode pattern 32 may include a connection electrode 40 connecting the ridge electrode 34 and the pad electrode 38. The connection electrode 40 may extend from the ridge electrode 34 along the second direction D2. The pad electrode 38 may be wider in width in the first direction D1 than the connection electrode 40. Part of the connection electrode 40 may be on one of the pair of projection structures 28.

The ridge-type semiconductor optical device may have a back electrode 42 widely on a back of the substrate 10. By injecting a current between the ridge electrode 34 and the back electrode 42, light emission occurs in the active layer 16 and light may be emitted from the end facet. The back electrode 42 does not necessarily have to be located on the back of the substrate 10. For example, a hole (not shown) reaching the substrate 10 may be formed in part of the projection structure 28, and an electrode (not shown) may be placed to be connected to it. In this case, the back electrode 42 may be placed on a top side, like the electrode pattern 32.

The ridge-type semiconductor optical device may have a protection film 44. The protection film 44 may be on each of the pair of projection structures 28. The highest position of the protection film 44 may be preferably closer to the mesa stripe structure 24. The protection film 44 may be located on the passivation film 30 on the top of the projection structures 28. The passivation film 30 may be interposed between each of the pair of projection structures 28 and the protection film 44. Therefore, the top of the protection film 44 may be higher in height from the substrate 10 than the top of the ridge electrode 34. If the protection film 44 and the ridge electrode 34 may be of the same material and thickness, their difference in height may be the thickness of the passivation film 30.

The protection film 44 may comprise a ductile material (e.g., metal, resin). The protection film 44 may be electrically separated from the electrode pattern 32 and may not contribute to driving, so it may not interfere with high-speed operation. The protection film 44 may be formed from metal in the same process as the electrode pattern 32, being advantageous in terms of manufacturability.

The material of the protection film 44 is not limited to metal but may be resin such as benzocyclobutene (BCB) or polyimide, as long as it is a ductile material. Even if the protection film 44 is formed from a different material than the electrode pattern 32, its height from the substrate 10 to the top may be greater than the height to the top of the ridge electrode 34. This can enhance a protection effect.

The protection film 44 and a corresponding one of the pair of projection structures 28 may be aligned at edges toward at least one orientation along the first direction D1. An edge of the protection film 44 and an upper edge of the inner surface of the groove 26 may be aligned with each other. The protection film 44 avoids an end, away from the mesa stripe structure 24 in the second direction D2, of each of the pair of projection structures 28. The protection film 44 may be on each of both sides sandwiching the connection electrode 40 in the first direction D1. An area of the protection film 44 may be in a position that overlaps, in the first direction D1, with at least part of the connection electrode 40. The area of the protection film 44 may be in a position that overlaps, in the first direction D1, with the pad electrode 38 as well.

The protection film 44 may include a pair of protection films 44A, 44B separated in the first direction D1. The protection films 44A and a corresponding one of the pair of projection structures 28 may be aligned at edges toward one orientation along the first direction D1. The protection film 44B and a corresponding one of the pair of projection structures 28 may be aligned at edges toward another orientation along the first direction D1.

To increase the protection effect, the protection film 44 should cover most of the top of the projection structure 28, but a stress caused by the protection film 44 may affect characteristics. The protection film 44 may be effective in terms of stress reduction if it does not extend over the entire top of the projection structure 28. The protection film 44 may have a width ⅕ or less of a width of the top of the projection structure 28, in the second direction D2.

A collet used in a manufacturing process of the ridge-type semiconductor optical device may be generally larger than a distance between the pair of projection structures 28, and the collet may not come into contact with only the mesa stripe structure 24 when it is applied from above, but the projection structure 28 may prevent the collet for pick-up from coming into contact with the mesa stripe structure 24.

Alternatively, the projection structure 28 may prevent the mesa stripe structure 24 from being broken by an external force. For example, when a sheet is pressed onto the top to be attached there, the top of the protection film 44, which may be highest, may prevent the sheet from strongly hitting the top (surface of the ridge electrode 34) of the mesa stripe structure 24.

The edge of the protection film 44 may be adjacent to an emission end face of the mesa stripe structure 24, reducing damage due to an impact applied near the emission end face. When the protection film 44 is not adjacent to the emission end face, only the passivation film 30 and projection structure 28 (laminate 12) may be near the emission end face. These materials may be brittle and may be subject to chipping upon impact. The chipping may be transmitted to the light emitting end face and may damage the light emitting end face.

In this example implementation, the protection film 44 may comprise a ductile material and may be positioned adjacent to the end face, thus absorbing external shock and preventing chipping. This can prevent the end face from being damaged.

This example implementation may be particularly applicable to a ridge-type semiconductor optical device for operation at 56 Gbps or higher and achieves improved characteristics of the ridge-type semiconductor optical device and protection of the mesa stripe structure 24.

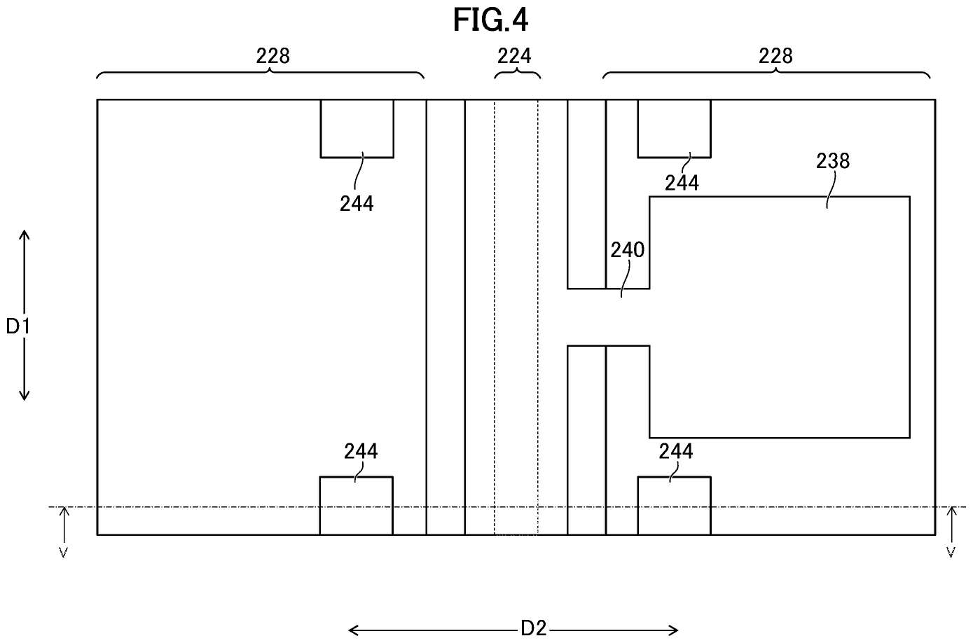

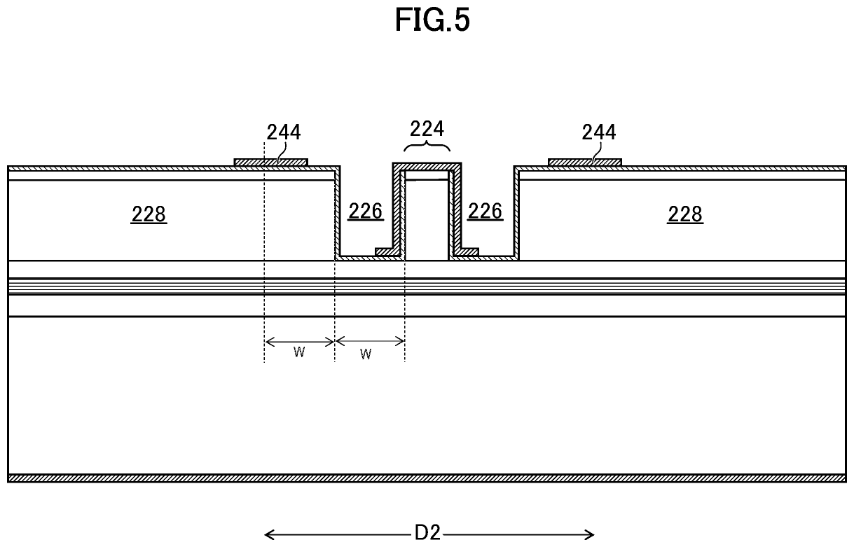

FIG. 4 is a plan view of a ridge-type semiconductor optical device in a second example implementation. FIG. 5 is a V-V cross-sectional view of the ridge-type semiconductor optical device in FIG. 4.

There may be a spacing in the second direction D2 between the edge of the protection film 244, facing the groove 226, and the edge of the corresponding one of the pair of projection structures 228, facing the groove 226. The spacing may be narrower than the width W of the groove 226 in the second direction D2. The edge of the protection film 244 should be within the width W of the groove 226 from the edge of the projection structure 228 in the direction away from the groove 226.

The closer the protection film 244 is to the mesa stripe structure 224, the better the protection of the mesa stripe structure 224. However, the protection film 244 and projection structure 228 do not necessarily need to be aligned at edges facing the groove 226.

The pad electrode 238 may be located on one projection structure 228 but may not be located on another projection structure 228. In contrast, the protection films 244 on each projection structure 228 may be arranged symmetrically about an axis along the first direction D1.

In other respects, the description in the first example implementation may be applicable. For example, an area of the protection film 244 may be in a position that overlaps, in the first direction D1, with the connection electrode 240 and the pad electrode 238. If a boundary line between the pad electrode 238 and the connection electrode 240 is not definitely clear, the boundary line may be at a position where a width in the first direction D1 begins to widen toward the pad electrode 238 from the connection electrode 240.

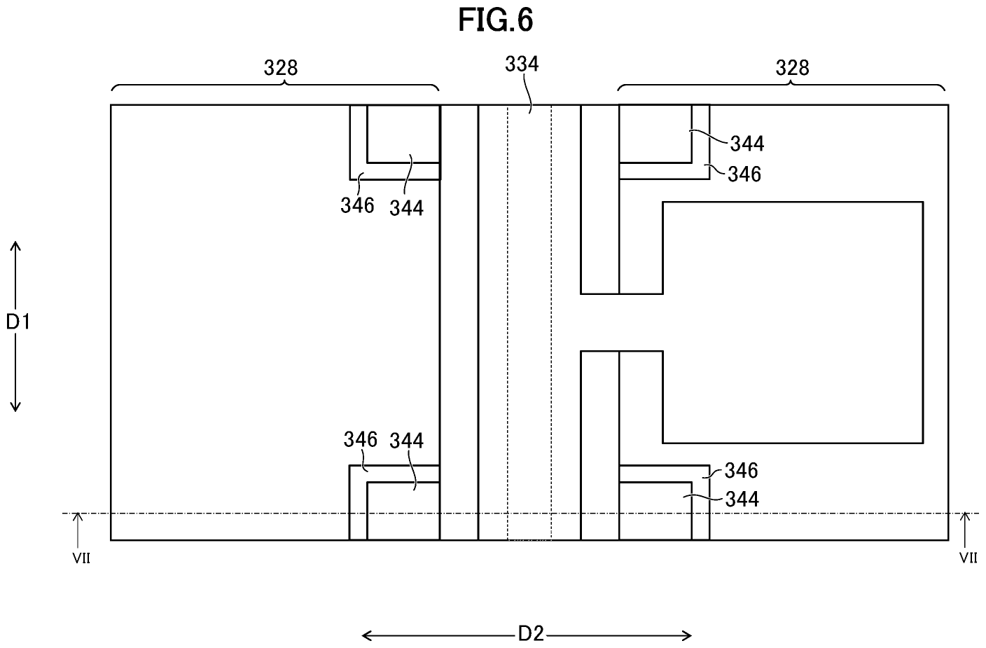

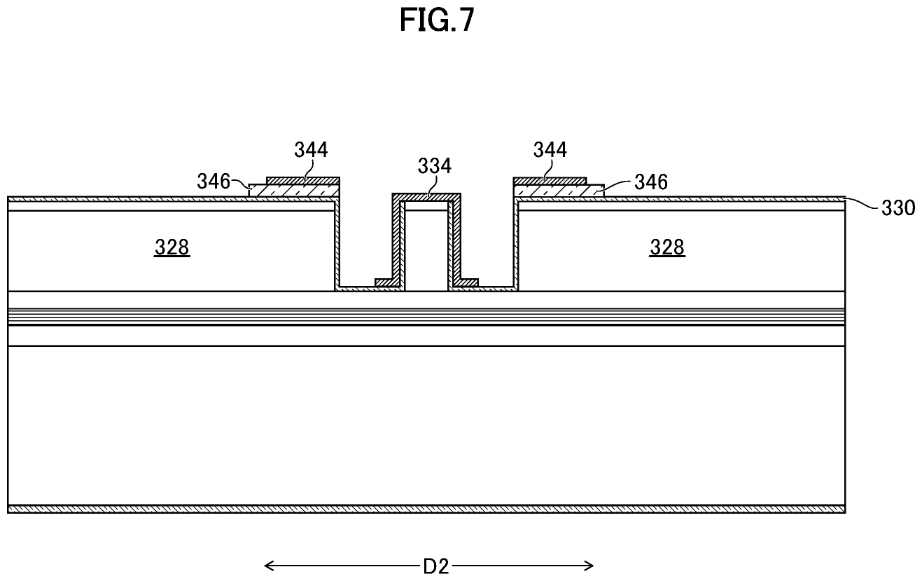

FIG. 6 is a plan view of a ridge-type semiconductor optical device in a third example implementation. FIG. 7 is a VII-VII cross-sectional view of the ridge-type semiconductor optical device in FIG. 6.

An insulating film 346 may be interposed between the passivation film 330 and the protection film 344. The insulating film 346 may comprise an insulating material such as an oxide film, a nitride film, or a resin. The insulating film 346 may be larger in planar shape than the protection film 344, but may not be limited to this, and the protection film 344 and insulating film 346 may partially overlap.

With the insulating film 346, a greater difference in height may be made between the top of the protection film 344 and the top of the ridge electrode 334, increasing the protection effect. Forming the insulating film 346 on the entire top of projection structure 328 may not be desirable, because it causes an increase in stress. The area of the insulating film 346 should not exceed four times the area of the protection film 344. In other respects, the description in the first example implementation may be applicable.

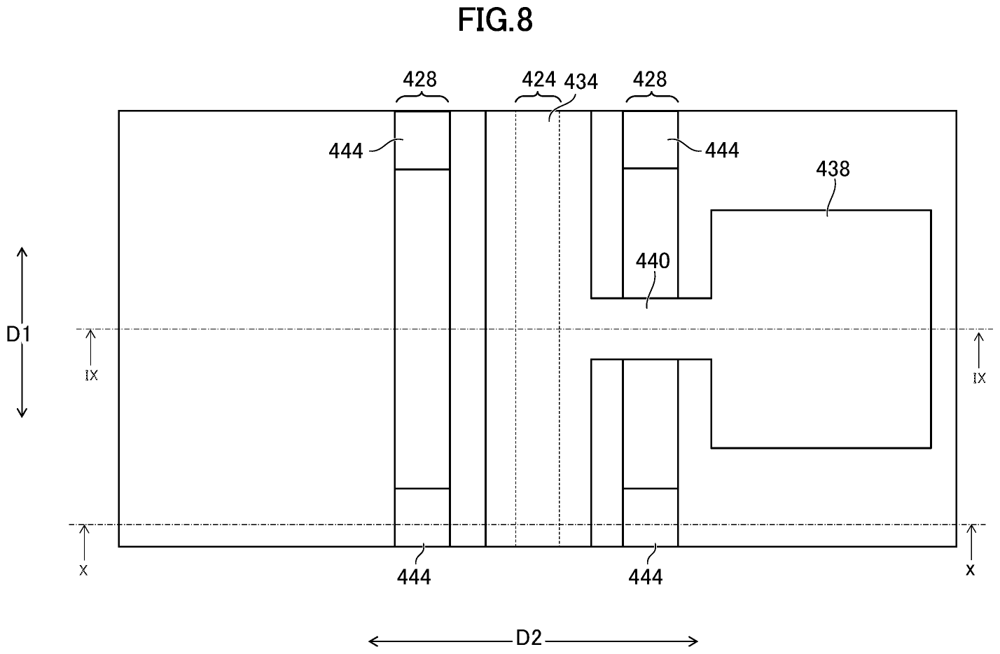

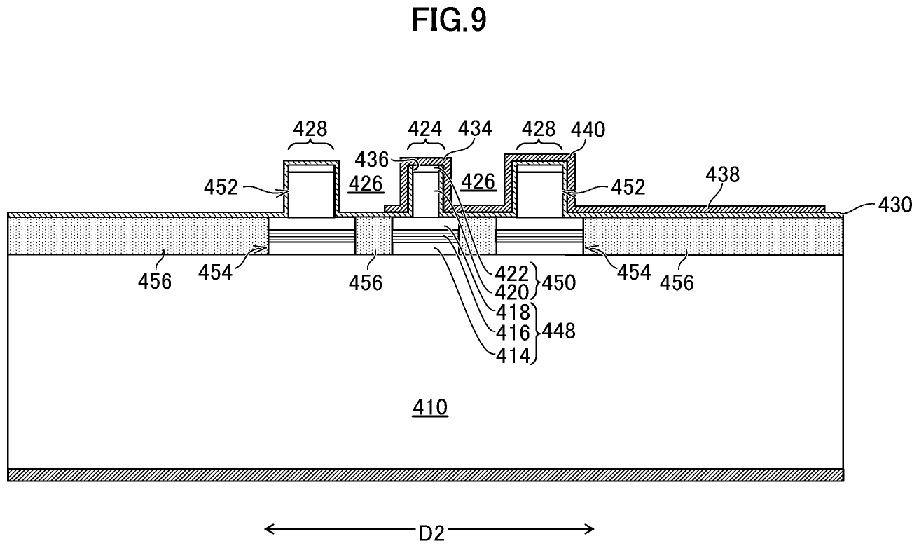

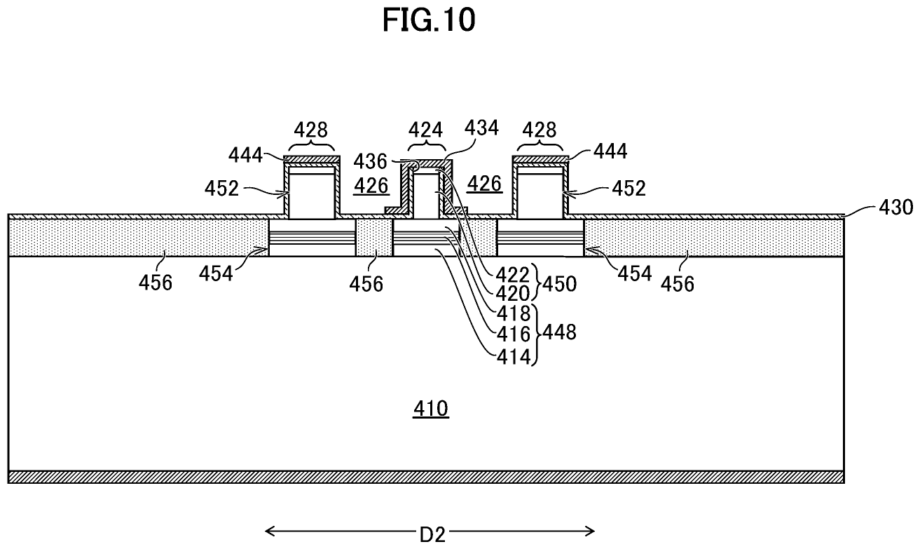

FIG. 8 is a plan view of the ridge-type semiconductor optical device in a fourth example implementation. FIG. 9 is a IX-IX cross-sectional view of the ridge-type semiconductor optical device in FIG. 8. FIG. 10 is a X-X cross-sectional view of the ridge-type semiconductor optical device in FIG. 8. In this example implementation, contrary to the first example implementation, the first conductivity type may be the p-type and the second conductivity type may be the n-type.

Above the substrate 410 may be a lower mesa stripe structure 448 extending in the first direction D1. The lower mesa stripe structure 448 may include a lower SCH layer 414 of the first conductivity type, an active layer 416, and an upper SCH layer 418 of the second conductivity type. Above the lower mesa stripe structure 448 may be an upper mesa stripe structure 450 extending in the first direction D1. The upper mesa stripe structure 450 may include a clad layer 420 of the second conductive type and a contact layer 422 of the second conductive type. The lower mesa stripe structure 448 may be wider in the second direction D2 than the upper mesa stripe structure 450.

The pair of projection structures 428 may avoid an end, in the second direction D2, of the substrate 410. Each projection structure 428 may include an upper projection structure 452 and a lower projection structure 454. Above the substrate 410 may be a lower projection structure 454 extending in the first direction D1. The lower projection structure 454 may include a lower SCH layer 414 of the first conductivity type, an active layer 416, and an upper SCH layer 418 of the second conductivity type. Above the lower projection structure 454 may be an upper projection structure 452 extending in the first direction D1. The upper mesa stripe structure 450 may include a clad layer 420 of the second conductivity type and a contact layer 422 of the second conductivity type. The lower projection structure 454 may be wider in the second direction D2 than the upper projection structure 452.

The ridge-type semiconductor optical device may have a buried layer 456 that covers the bottom portion (lower mesa stripe structure 448), avoiding the top portion (upper mesa stripe structure 450), of the mesa stripe structure 424. The buried layer 456 may be an insulating or semi-insulating semiconductor layer, a semiconductor layer comprising multiple semiconductor layers of first and second conductive types, or a semiconductor layer comprising multiple semiconductors of insulating, first conductive, and second conductive types.

The buried layer 456 covers the bottom portion (lower projection structure 454) avoiding the top portion (upper projection structure 452) of projection structure 428. The buried layer 456 may be also adjacent to the side, opposite to the groove 426, of the lower projection structure 454. The buried layer 456 and substrate 410 may be aligned at edges opposite to the groove 426. The buried layer 456 may extend to both ends, in the first direction D1, of the substrate 410.

There may be grooves 426 on both sides of the upper mesa stripe structure 450. The groove 426 may separate the clad layer 420 and the contact layer 422, and may extend in the direction D1. Each projection structure 428 and the mesa stripe structure 424 may be separated by the groove 426. The upper mesa stripe structure 450, the lower mesa stripe structure 448, the groove 426, the upper projection structure 452, and the lower projection structure 454 may be formed from the emitting end face to the opposite end face in the first direction D1.

The passivation film 430 may be located on the top of the buried layer 456 (except for some portions), the side and the top of the upper projection structure 452, the inner surface of the groove 426, and the side of the upper mesa stripe structure 450. The passivation film 430 may not be formed on the top of the upper mesa stripe structure 450 and may have a through-hole 436 for connection between the ridge electrode 434 and the contact layer 422.

The ridge electrode 434 may be on the top and the side of the upper mesa stripe structure 450. The ridge electrode 434 may extend in the second direction D2. The ridge electrode 434 and the mesa stripe structure 424 may be aligned at respective ends in the first direction D1. The side end, in the second direction D2, of the ridge electrode 434 may be in the groove 426 and may not reach the upper projection structure 452.

The pad electrode 438 may be on the substrate 410 except on the pair of projection structures 428. The pad electrode 438 may be used for external electrical connection, for an unillustrated wire to be bonded to it, or to be bonded by solder. Part of the connection electrode 440 may be on one of the pair of projection structures 428.

A protection film 444 may be placed on the projection structure 428. The protection film 444 may be placed on the passivation film 430. The edge of the protection film 444 and the upper end of the inner surface of the groove 426 may be aligned. The area of the protection film 444 may be in a position that overlaps, in the first direction D1, with the pad electrode 438. In other respects, the description in the first example implementation may be applicable.

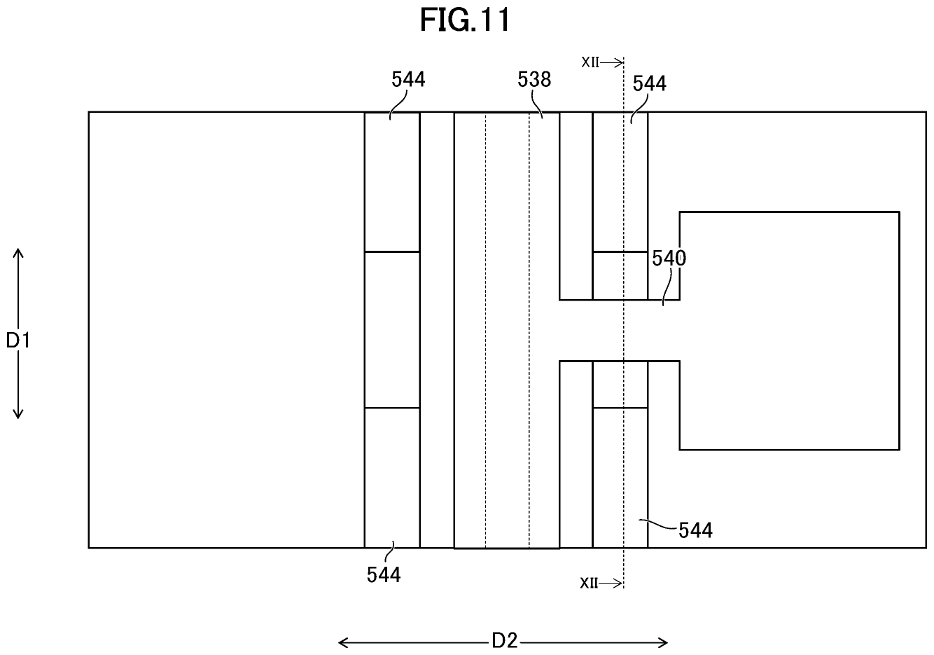

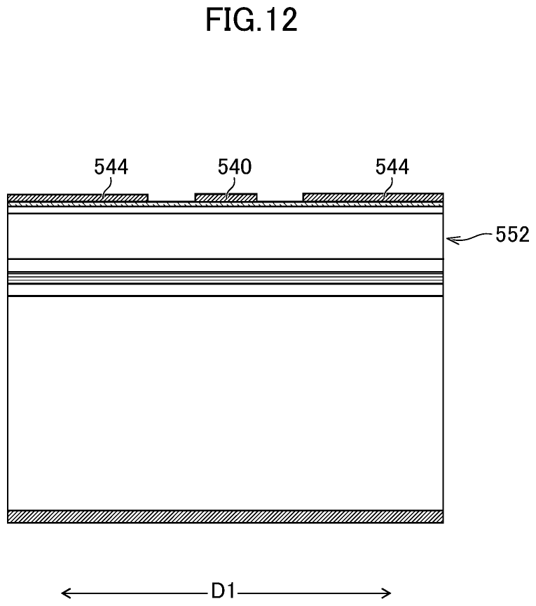

FIG. 11 is a plan view of a ridge-type semiconductor optical device in a fifth example implementation. FIG. 12 is a XII-XII cross-sectional view of the ridge-type semiconductor optical device in FIG. 11. In this example implementation, the protection film 544 may be longer in the first direction D1 than in the fourth example implementation. This enhances the protection effect but causes an increase in stress, so the protection film 544 should have a length, in the first direction D1, ⅓ or less of the upper projection structure 552.

In other respects, the description in the fourth example implementation may be applicable. The protection film 544 may be disposed on the top of one upper projection structure 552 so as to sandwich the connection electrode 540. On the top of another upper projection structure 552, where the connection electrode 540 may not be disposed, the pair of protection films 544 may not be continuous. All the four protection films 544 may have the same shape.

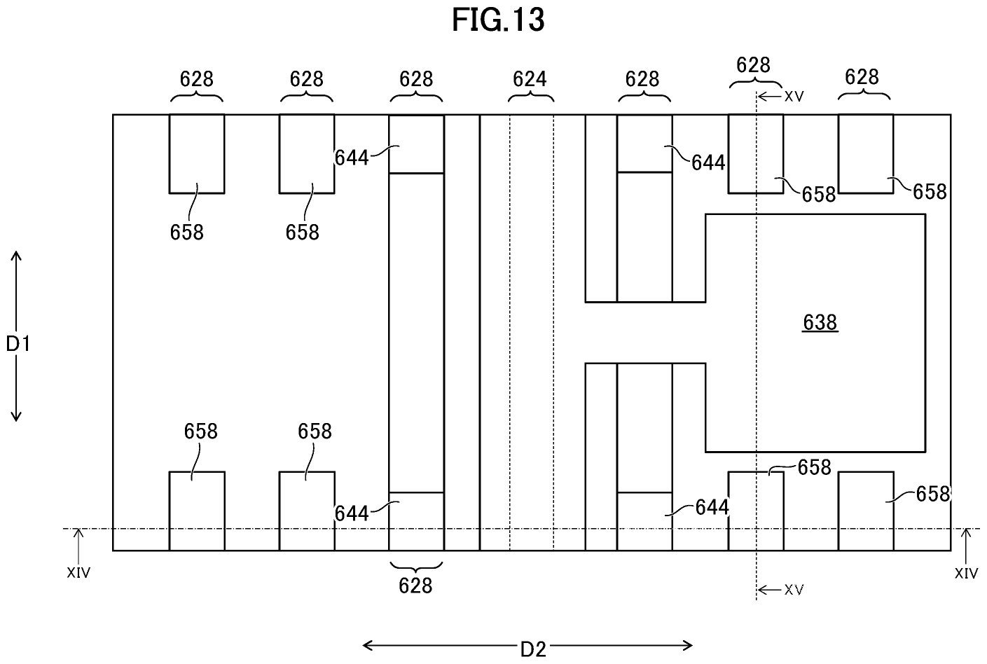

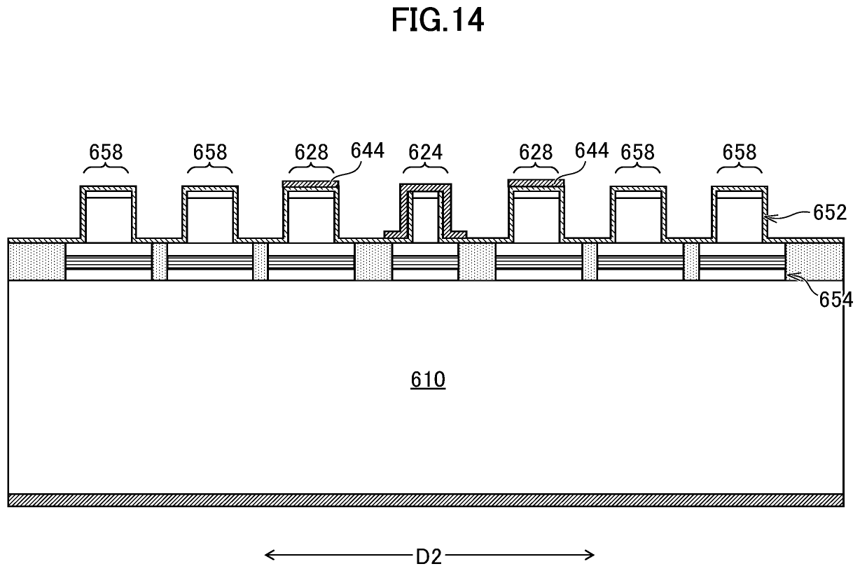

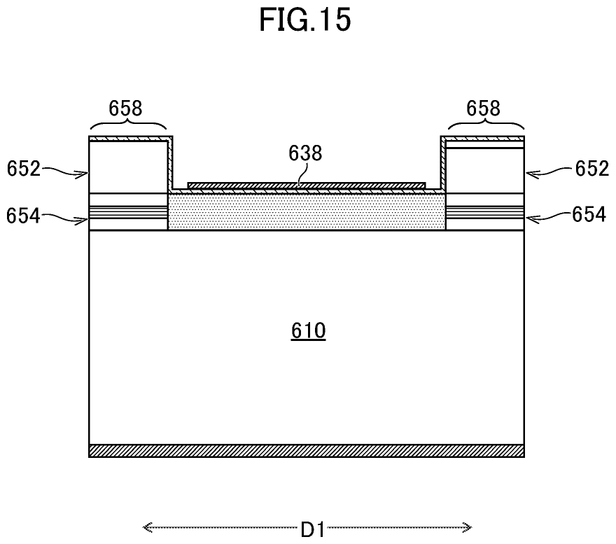

FIG. 13 is a plan view of a ridge-type semiconductor optical device in a sixth example implementation. FIG. 14 is a XIV-XIV cross-sectional view of the ridge-type semiconductor optical device in FIG. 13. FIG. 15 is a XV-XV cross-sectional view of the ridge-type semiconductor optical device in FIG. 13.

Each projection structure 628 may include some projection structures 628 separated in the second direction D2. At least one of the projection structures 628 may be separated in the first direction D1. There may be eight separate projection structures 658, each of which may include an upper projection structure 652 and a lower projection structure 654 in a configuration in a lamination direction. The separate projection structure 658 and the substrate 610 may be aligned at edges toward only one orientation along the first direction D1.

By separating the projection structure 628, the pad electrode 638 may be placed on the substrate 610 except on the pair of projection structures 628. When not separated, the pad electrode 638 may have a portion on the substrate 610 and another portion on the projection structure 628, creating unevenness on a surface. The unevenness may be undesirable because it reduces connection strength of wire bonding. Part of the connection electrode 640 may be on one of the pair of projection structures 628.

The projection structure 628 opposite to the pad electrode 638 also may include some projection structures 628 separated in the second direction D2, and at least one of the projection structures 628 may be separated into separate projection structures 658. The projection structure 628 may not have to be separated, but making the pair of projection structures 628 symmetrical may be superior in terms of stress and manufacturing stability.

The protection film 644 may be at least on the projection structure 628 closest to the mesa stripe structure 624 (not separated in the first direction D1) of the projection structures 628. No protection film 644 may be disposed on the top of the separate projection structure 658. In other respects, the description in the fourth example implementation may be applicable.

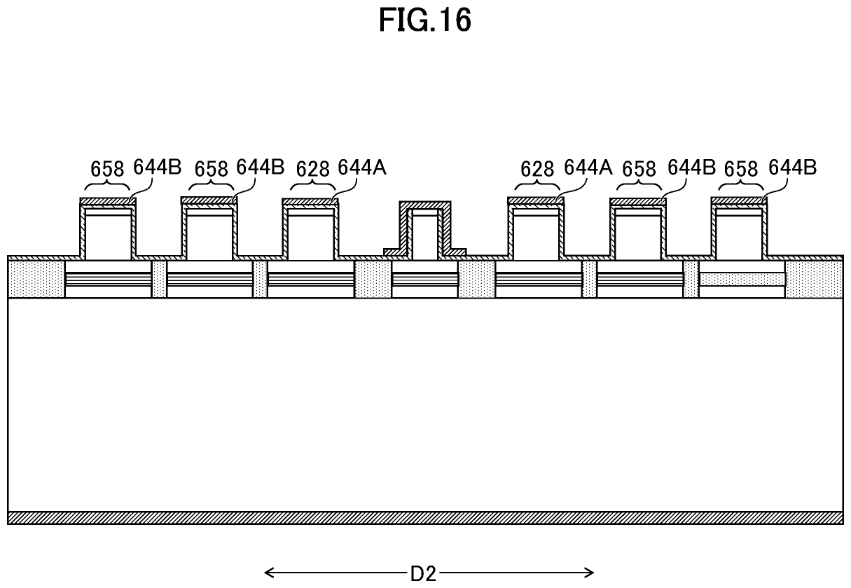

FIG. 16 is a cross-sectional view of a ridge-type semiconductor optical device in a modification of the sixth example implementation. The protection films 644A, 644B may be on all of the projection structures 628 and thus also on the separate projection structures 658. An area of the protection film 644A closest to the mesa stripe structure 624 may be in a position that avoids overlap, in the first direction D1, with the pad electrode 638 (see FIG. 13). An area of the protection film 644B not closest to the mesa stripe structure 624 may be in a position that overlaps, in the first direction D1, with the pad electrode 638 (see FIG. 13).

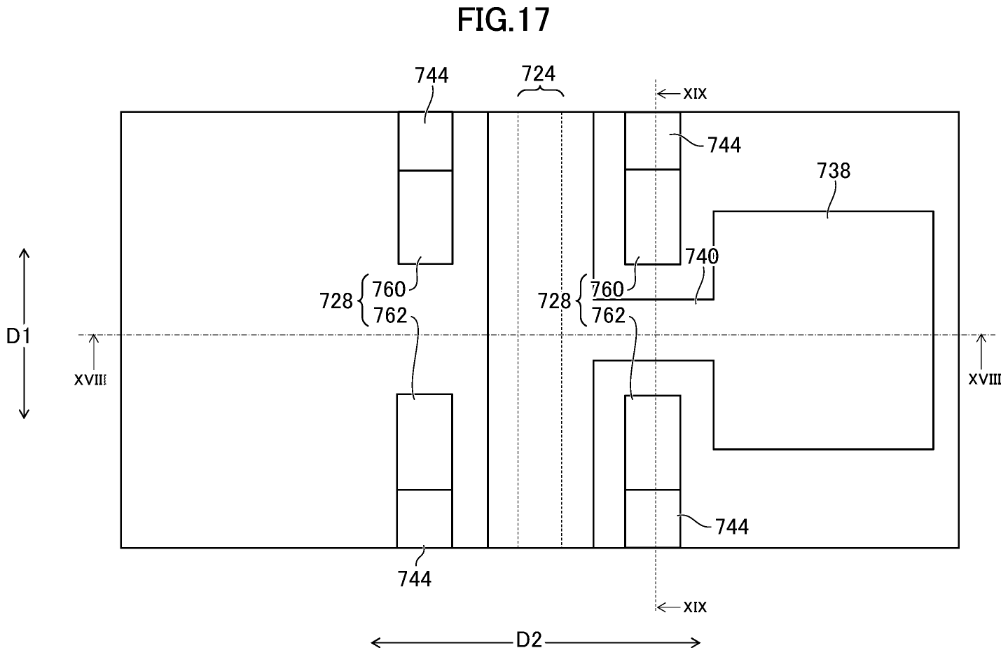

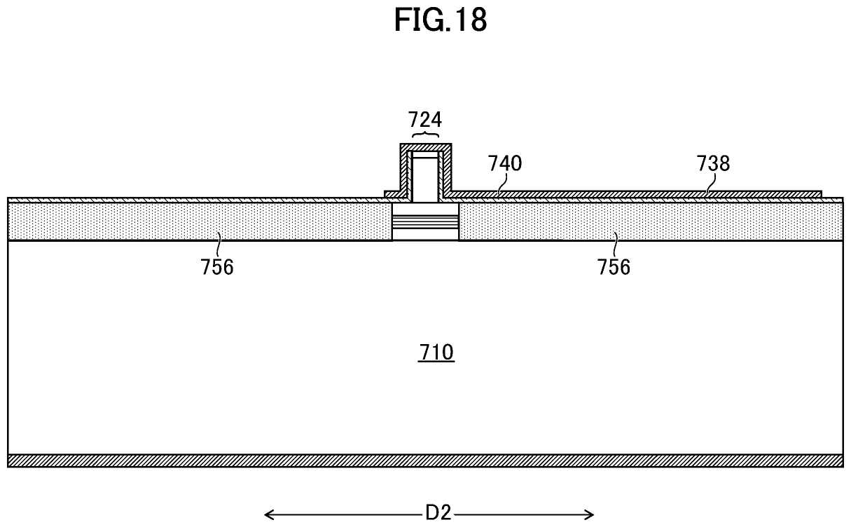

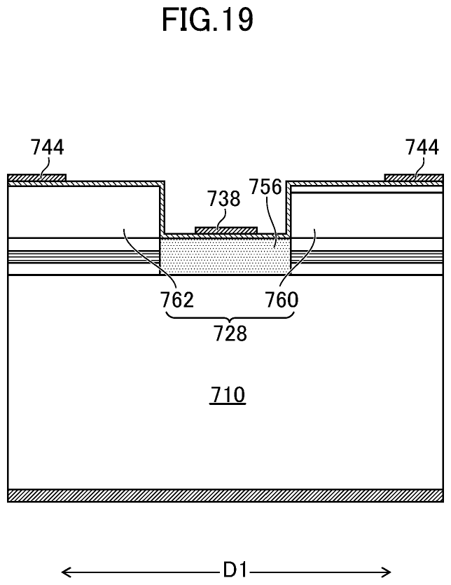

FIG. 17 is a plan view of a ridge-type semiconductor optical device in a seventh example implementation. FIG. 18 is an XVIII-XVIII cross-sectional view of the ridge-type semiconductor optical device in FIG. 17. FIG. 19 is a XIX-XIX cross-sectional view of the ridge-type semiconductor optical device in FIG. 17.

At least one (e.g., both) of the pair of projection structures 728 may include a first projection structure 760 and a second projection structure 762 separated in the first direction D1. The first projection structure 760 and the substrate 710 may be aligned at edges toward one orientation along the first direction D1. The second projection structure 762 and the substrate 710 may be aligned at edges toward another orientation along the first direction D1. The connection electrode 740 may be on the substrate 710 except on the pair of projection structures 728. Therefore, no large step may be formed on the connection electrode 740 and no step breakage occurs, resulting in excellent reliability of electrical connectivity. On a side where the connection electrode 740 is not led out, the projection structure 728 may be continuous in the first direction D1.

In other respects, the description in the fourth example implementation may be applicable. The protection film 744 may be disposed on part of the top of the projection structure 728, but may be disposed on the entire surface. An area of the protection film 744 may be in a position that avoids overlap, in the first direction D1, with the pad electrode 738. The ridge-type semiconductor optical device may have a buried layer 756 that covers a bottom portion, avoiding a top portion, of the mesa stripe structure 724.

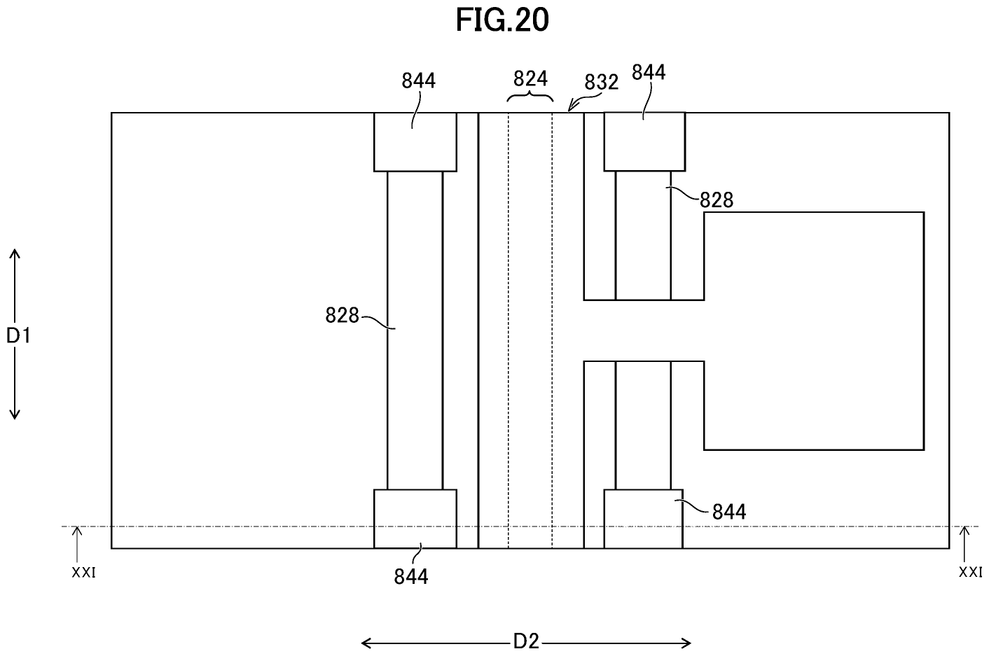

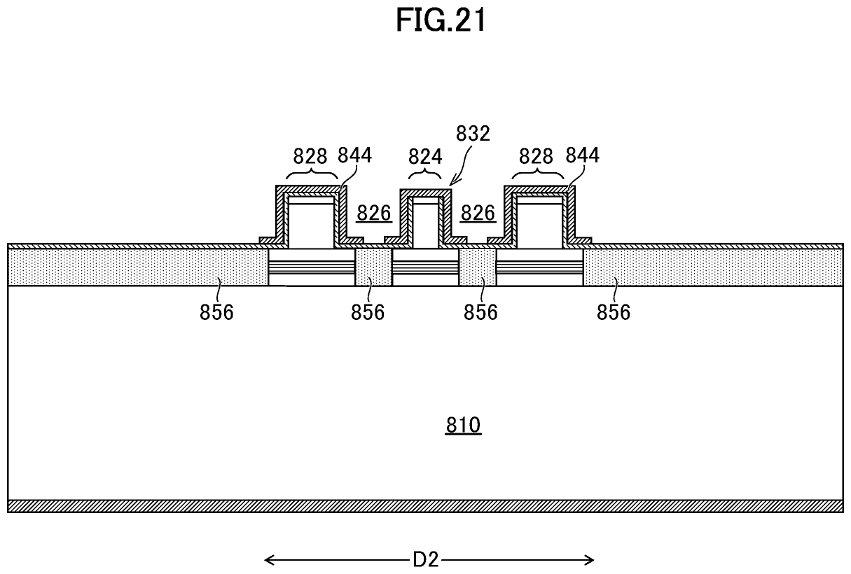

FIG. 20 is a plan view of a ridge-type semiconductor optical device in an eighth example implementation. FIG. 21 is a XXI-XXI cross-sectional view of the ridge-type semiconductor optical device in FIG. 20.

The protection film 844 reaches at least one (e.g., both sides) of the side facing the groove 826 and the opposite side of the corresponding one of the pair of projection structures 828. Thus, the protection film 844 may be positioned beyond the top of the projection structure 828. The width of the protection film 844 should be ⅕ or less of the length in the second direction D2 from the side, facing the groove 826, of the projection structure 828 to the edge of the substrate 810.

The protection film 844 may be adjacent to the projection structure 828 and formed also on the buried layer 856. However, the protection film 844 must be electrically insulated from the electrode pattern 832.

Forming the protection film 844 beyond the top of the projection structure 828 in the second direction D2 may be combined with other embodiments. For example, in combination with the first example implementation, the protection film 44 may cover the side of the projection structure 28 (passivation film 30) and may have an edge in the inner surface of the groove 26. However, the protection film 44 may be electrically insulated from the electrode pattern 32. In other respects, the description in the fourth example implementation may be applicable.

The embodiments described above are not limited and different variations are possible. The structures explained in the embodiments may be replaced with substantially the same structures and other structures that can achieve the same effect or the same objective.

In a first implementation, a ridge-type semiconductor optical device comprises: a substrate 10; a mesa stripe structure 24 on the substrate 10, the mesa stripe structure 24 extending in a first direction D1, the mesa stripe structure 24 comprising a brittle material; an electrode pattern 32 including a ridge electrode 34 on the mesa stripe structure 24; a pair of projection structures 28 on the substrate 10 and on both sides of the mesa stripe structure 24 in a second direction D2 perpendicular to the first direction D1; and a protection film 44 on each of the pair of projection structures 28, the protection film 44 being separated from the electrode pattern 32, the protection film 44 comprising a ductile material, the protection film 44 and a corresponding one of the pair of projection structures 28 being aligned at edges toward at least one orientation along the first direction D1, the protection film 44 having a top higher from the substrate 10 than a top of the ridge electrode 34.

The protection film 44 may be higher in height from the substrate 10 than the top of the ridge electrode 34, preventing damage to the mesa stripe structure 24.

In a second implementation, alone or in combination with the first implementation, the protection film 44 includes a pair of protection films 44A, 44B separated in the first direction D1. one of the pair of protection films 44A, 44B and the corresponding one of the pair of projection structures 28 are lined up at edges toward one orientation along the first direction D1, and another of the pair of protection films 44A, 44B and the corresponding one of the pair of projection structures 28 are lined up at edges toward another orientation along the first direction D1.

In a third implementation, alone or in combination with one or more of the first and second implementations, each of the pair of projection structures 28 and the mesa stripe structure 24 are separated by a groove 26 and the protection film 44 has an edge lined up with an upper end of an inner surface of the groove 26.

In a fourth implementation, alone or in combination with one or more of the first through third implementations, each of the pair of projection structures 228 and the mesa stripe structure 224 are separated by a groove 226, and there is a spacing, in the second direction D2, between an edge, facing the groove 226, of the protection film 244 and an edge, facing the groove 226, of the corresponding one of the pair of projection structures 228.

In a fifth implementation, alone or in combination with one or more of the first through fourth implementations, the spacing is narrower than a width W of the groove 226 in the second direction D2.

In a sixth implementation, alone or in combination with one or more of the first through fifth implementations, each of the pair of projection structures 828 and the mesa stripe structure 824 are separated by a groove 826, and the protection film 844 reaches at least one of a side facing the groove 826 and an opposite side, of the corresponding one of the pair of projection structures 828.

In a seventh implementation, alone or in combination with one or more of the first through sixth implementations, the protection film 44 avoids an end, away from the mesa stripe structure 24 in the second direction D2, of each of the pair of projection structures 28.

In an eighth implementation, alone or in combination with one or more of the first through seventh implementations, the substrate 10 and each of the pair of projection structures 28 are lined up at edges in a direction away from the mesa stripe structure 24.

In a ninth implementation, alone or in combination with one or more of the first through eighth implementations, the pair of projection structures 428 avoid an end, in the second direction D2, of the substrate 410.

In a tenth implementation, alone or in combination with one or more of the first through ninth implementations, each of the pair of projection structures 628 includes some projection structures 628 separated in the second direction D2, and the protection film 644 is at least on one of the projection structures 628 closest to the mesa stripe structure 624.

In an eleventh implementation, alone or in combination with one or more of the first through tenth implementations, wherein at least one of the projection structures 628 is separated in the first direction D1.

In a twelfth implementation, alone or in combination with one or more of the first through eleventh implementations, at least one of the pair of projection structures 728 includes a first projection structure 760 and a second projection structure 762 separated in the first direction D1.

In a thirteenth implementation, alone or in combination with one or more of the first through twelfth implementations, the first projection structure 760 and the substrate 710 are lined up at edges toward one orientation along the first direction D1, and the second projection structure 762 and the substrate 710 are lined up at edges toward another orientation along the first direction D1.

In a fourteenth implementation, alone or in combination with one or more of the first through thirteenth implementations, the electrode pattern 32 further includes a pad electrode 38 and a connection electrode 40 connecting the ridge electrode 34 and the pad electrode 38, the connection electrode 40 extends from the ridge electrode 34 along the second direction D2, and the pad electrode 38 is wider in the first direction D1 than the connection electrode 40.

In a fifteenth implementation, alone or in combination with one or more of the first through fourteenth implementations, the pad electrode 38 may be on one of the pair of projection structures 28.

In a sixteenth implementation, alone or in combination with one or more of the first through fifteenth implementations, the pad electrode 438 is on the substrate 410 except on the pair of projection structures 428.

In a seventeenth implementation, alone or in combination with one or more of the first through sixteenth implementations, part of the connection electrode 40 is on one of the pair of projection structures 28.

In an eighteenth implementation, alone or in combination with one or more of the first through seventeenth implementations, the connection electrode 740 is on the substrate 710 except on the pair of projection structures 728.

In an nineteenth implementation, alone or in combination with one or more of the first through eighteenth implementations, an area of the protection film 44 is in a position that overlaps, in the first direction D1, with at least part of the connection electrode 40.

In a twentieth implementation, alone or in combination with one or more of the first through nineteenth implementations, the area of the protection film 44 is in a position that overlaps, in the first direction D1, with the pad electrode 38 as well.

In a twenty-first implementation, alone or in combination with one or more of the first through twentieth implementations, wherein the area of the protection film 444 is in a position that avoids overlap, in the first direction D1, with the pad electrode 438.

In a twenty-second implementation, alone or in combination with one or more of the first through twenty-first implementations, the area of the protection film 544 is in a position that overlaps, in the second direction D2, with the pad electrode 538.

In a twenty-third implementation, alone or in combination with one or more of the first through twenty-second implementations, wherein the protection film 44 is on each of both sides sandwiching the connection electrode 40 in the first direction D1.

In a twenty-fourth implementation, alone or in combination with one or more of the first through twenty-third implementations, the ridge-type semiconductor optical device further comprises a passivation film 30 interposed between each of the pair of projection structures 28 and the protection film 44, except under the ridge electrode 34.

In a twenty-fifth implementation, alone or in combination with one or more of the first through twenty-fourth implementations, the ridge-type semiconductor optical device further comprises an insulating film 346 interposed between the passivation film 330 and the protection film 344.

In a twenty-sixth implementation, alone or in combination with one or more of the first through twenty-fifth implementations, the ridge-type semiconductor optical device further comprises a buried layer 456 covering a bottom portion, except a top portion, of the mesa stripe structure 424.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A ridge-type semiconductor optical device comprising:
a substrate;
a mesa stripe structure on the substrate, the mesa stripe structure extending in a first direction, the mesa stripe structure comprising a brittle material;
an electrode pattern including a ridge electrode on the mesa stripe structure;
a pair of projection structures on the substrate and on both sides of the mesa stripe structure in a second direction perpendicular to the first direction; and
a protection film on each of the pair of projection structures, the protection film being separated from the electrode pattern, the protection film comprising a ductile material,
the protection film and a corresponding one of the pair of projection structures being aligned at edges toward at least one orientation along the first direction,
the protection film having a top higher from the substrate than a top of the ridge electrode.

2. The ridge-type semiconductor optical device according to claim 1, wherein:
the protection film includes a pair of protection films separated in the first direction.
one of the pair of protection films and the corresponding one of the pair of projection structures are aligned at edges toward one orientation along the first direction, and
another of the pair of protection films and the corresponding one of the pair of projection structures are aligned at edges toward another orientation along the first direction.

3. The ridge-type semiconductor optical device according to claim 1, wherein:
each of the pair of projection structures and the mesa stripe structure are separated by a groove and
the protection film has an edge aligned with an upper end of an inner surface of the groove.

4. The ridge-type semiconductor optical device according to claim 1, wherein:
each of the pair of projection structures and the mesa stripe structure are separated by a groove, and
there is a spacing, in the second direction, between an edge, facing the groove, of the protection film and an edge, facing the groove, of the corresponding one of the pair of projection structures.

5. The ridge-type semiconductor optical device according to claim 4, wherein the spacing is narrower than a width of the groove in the second direction.

6. The ridge-type semiconductor optical device according to claim 1, wherein:
each of the pair of projection structures and the mesa stripe structure are separated by a groove, and
the protection film reaches at least one of a side facing the groove and an opposite side, of the corresponding one of the pair of projection structures.

7. The ridge-type semiconductor optical device according to claim 1, wherein the protection film avoids an end, away from the mesa stripe structure in the second direction, of each of the pair of projection structures.

8. The ridge-type semiconductor optical device according to claim 1, wherein the substrate and each of the pair of projection structures are aligned at edges in a direction away from the mesa stripe structure.

9. The ridge-type semiconductor optical device according to claim 1, wherein the pair of projection structures avoid an end, in the second direction, of the substrate.

10. The ridge-type semiconductor optical device according to claim 1, wherein:
each of the pair of projection structures includes some projection structures separated in the second direction, and
the protection film is at least on one of the projection structures closest to the mesa stripe structure.

11. The ridge-type semiconductor optical device according to claim 10, wherein at least one of the projection structures is separated in the first direction.

12. The ridge-type semiconductor optical device according to claim 1, wherein at least one of the pair of projection structures includes a first projection structure and a second projection structure separated in the first direction.

13. The ridge-type semiconductor optical device according to claim 12, wherein:
the first projection structure and the substrate are aligned at edges toward one orientation along the first direction, and
the second projection structure and the substrate are aligned at edges toward another orientation along the first direction.

14. The ridge-type semiconductor optical device according to claim 1, wherein:
the electrode pattern further includes a pad electrode and a connection electrode connecting the ridge electrode and the pad electrode,
the connection electrode extends from the ridge electrode along the second direction, and
the pad electrode is wider in the first direction than the connection electrode.

15. The ridge-type semiconductor optical device according to claim 14, wherein the pad electrode is on one of the pair of projection structures.

16. The ridge-type semiconductor optical device according to claim 14, wherein the pad electrode is on the substrate except on the pair of projection structures.

17. The ridge-type semiconductor optical device according to claim 14, wherein part of the connection electrode is on one of the pair of projection structures.

18. The ridge-type semiconductor optical device according to claim 14, wherein the connection electrode is on the substrate except on the pair of projection structures.

19. The ridge-type semiconductor optical device according to claim 14, wherein an area of the protection film is in a position that overlaps, in the first direction, with at least part of the connection electrode.

20. The ridge-type semiconductor optical device according to claim 19, wherein the area of the protection film is in a position that overlaps, in the first direction, with the pad electrode as well.

21. The ridge-type semiconductor optical device according to claim 19, wherein the area of the protection film is in a position that avoids overlap, in the first direction, with the pad electrode.

22. The ridge-type semiconductor optical device according to claim 21, wherein the area of the protection film is in a position that overlaps, in the second direction, with the pad electrode.

23. The ridge-type semiconductor optical device according to claim 14, wherein the protection film is on each of both sides sandwiching the connection electrode in the first direction.

24. The ridge-type semiconductor optical device according to claim 1, further comprising a passivation film interposed between each of the pair of projection structures and the protection film, except under the ridge electrode.

25. The ridge-type semiconductor optical device according to claim 24, further comprising an insulating film interposed between the passivation film and the protection film.

26. The ridge-type semiconductor optical device according to claim 1, further comprising a buried layer covering a bottom portion, except a top portion, of the mesa stripe structure.
